(19) United States
(12) Patent Application Publication
(10) Pub. No.: US 2015/0008029 A1
(43) Pub. Date: Jan. 8, 2015

(54) CIRCUIT BOARD AND METHOD OF MANUFACTURING THE SAME

(71) Applicant: BOARDTEK ELECTRONICS CORPORATION, TAOYUAN COUNTY (TW)

(72) Inventor: CHIEN-CHENG LEE, TAOYUAN COUNTY (TW)

(73) Assignee: BOARDTEK ELECTRONICS CORPORATION, TAOYUAN COUNTY (TW)

(21) Appl. No.: 14/063,053

(22) Filed: Oct. 25, 2013

(30) Foreign Application Priority Data
Jul. 8, 2013 (TW) 102124353

(51) Int. Cl. H05K 1/11; H05K 3/42

(52) U.S. Cl. CPC H05K 1/115; H05K 3/429
USPC 174/266; 29/852

(57) ABSTRACT

A circuit board includes a substrate and a through via. The substrate has a first surface and a second surface opposite to the first surface. The substrate includes circuit layers and insulation layers. The insulation layers are sandwiched between the circuit layers. The through via goes through the substrate and has portions defining a first portion and a second portion. The first portion of the through via is coated with a first metal layer and electrically connected to at least one of the circuit layer by the first metal layer. The second portion of the through via is coated with a second metal layer and electrically connected to at least one of the circuit layer by the second metal layer. The first and second portions are electrically insulted, and the diameter of the second portion is larger than that of the first portion.

### BACKGROUND

1. Field of the Invention

The instant disclosure relates to a circuit board; in particular, to a method of manufacturing circuit board.

2. Description of Related Art

Current electronic products, for example, mobile phones and laptops, have higher module density because of the compact size and multiple functions. Different routing designs are laid out on a circuit board. In general, different circuit layers are connected by vias.

Though via, blind via or buried via is commonly seen microvia for establishing electrical connection. The wall of the hole is plated with metallic material to form plated through via, plated blind via or plated buried via. Plated through via goes through all the circuit layers which occupies considerate amount of space. Plated blind via or buried via goes through some of the circuit layers. However, individual circuit layer has to be drilled and then attached together which requires higher cost.

### BRIEF SUMMARY OF THE INVENTION

The instant disclosure provides a circuit board having through via that has portions defining separate openings.

According to one embodiment of the instant disclosure, the circuit board includes a substrate and a through via. The substrate has a first surface and a second surface opposite to the first surface. The substrate includes a plurality of circuit layers and a plurality of insulation layers. The insulation layers are alternatively sandwiched between the circuit layers. The through via goes through the substrate. The through via has portions defining a first portion and a second portion. The first portion of the through via is coated with a first metal layer and electrically connected to at least one of the circuit layer by the first metal layer. The second portion of the through via is coated with a second metal layer and electrically connected to at least one of the circuit layer by the second metal layer. The first and second portions are electrically insulted, and the diameter of the second portion is larger than that of the first portion.

The instant disclosure also provides a method of manufacturing circuit board having through via that has portions defining separate openings.

According to one embodiment of the instant disclosure, the method of manufacturing circuit board includes, firstly, providing a substrate. The substrate has a first surface and a second surface opposite to the first surface. The substrate includes a plurality of circuit layers and a plurality of insulation layers. The insulation layers are alternatively sandwiched between the circuit layers. Secondly, a first hole which goes through the first surface and a portion of the substrate is formed. Thirdly, a second hole which goes through the second surface and a portion of the substrate is formed to meet the first hole. The diameter of the second hole is larger than that of the first hole. Subsequently, a metal layer is electroplated onto the wall of the first and second holes. Finally, A part of metal layer that separated to two parts at the boundary of the first and second holes is removed to form a through via.

In summary, the circuit board has a through via defining the first and second portions. The first portion of the through via is coated with a first metal layer and electrically connected to at least one of the circuit layer by the first metal layer. The second portion of the through via is coated with a second metal layer and electrically connected to at least one of the circuit layer by the second metal layer. The first and second portions are electrically insulted, and the diameter of the second portion is larger than that of the first portion. Accordingly, the electrical connection between different circuit layers is shortened, and therefore the signal transmission speed increases. In addition, the space occupied by the through via can be used for other layer of layer interconnection.

In order to further understand the instant disclosure, the following embodiments are provided along with illustrations to facilitate the appreciation of the instant disclosure; however, the appended drawings are merely provided for reference and illustration, without any intention to be used for limiting the scope of the instant disclosure.

### BRIEF DESCRIPTION OF THE SEVERAL VIEWS OF THE DRAWINGS

FIG. 1A is a schematic diagram showing a circuit board in accordance with a first embodiment of the instant disclosure;

FIG. 1B is a schematic diagram showing a circuit board in accordance with a second embodiment of the instant disclosure;

FIGS. 2A to 2E are schematic diagrams showing steps of manufacturing a circuit board in accordance with a first embodiment of the instant disclosure;

FIGS. 3A to 3C are schematic diagrams showing steps of manufacturing a circuit board in accordance with a second embodiment of the instant disclosure; and

FIG. 4 shows a half finished product in accordance with an embodiment of the instant disclosure.

### DETAILED DESCRIPTION OF THE INVENTION

The aforementioned illustrations and following detailed descriptions are exemplary for the purpose of further explaining the scope of the instant disclosure. Other objectives and advantages related to the instant disclosure will be illustrated in the subsequent descriptions and appended drawings.

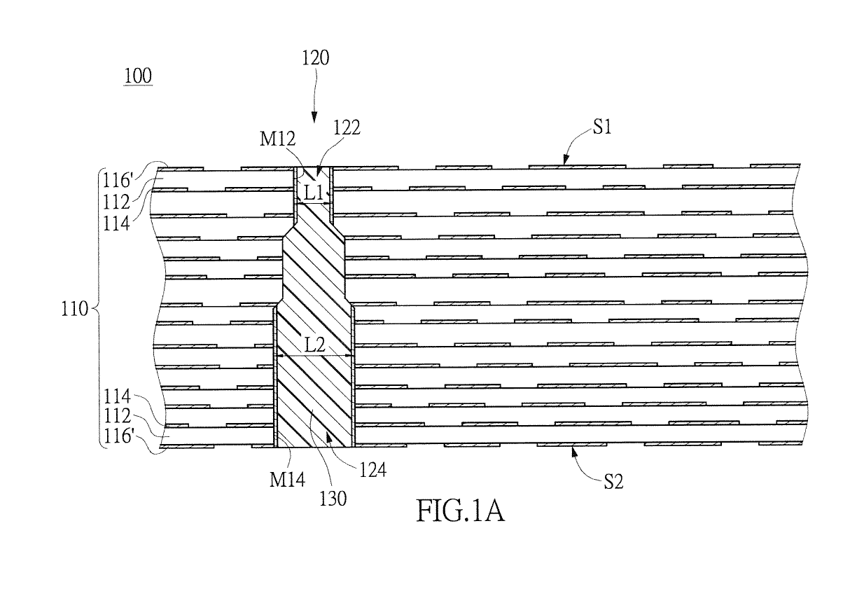

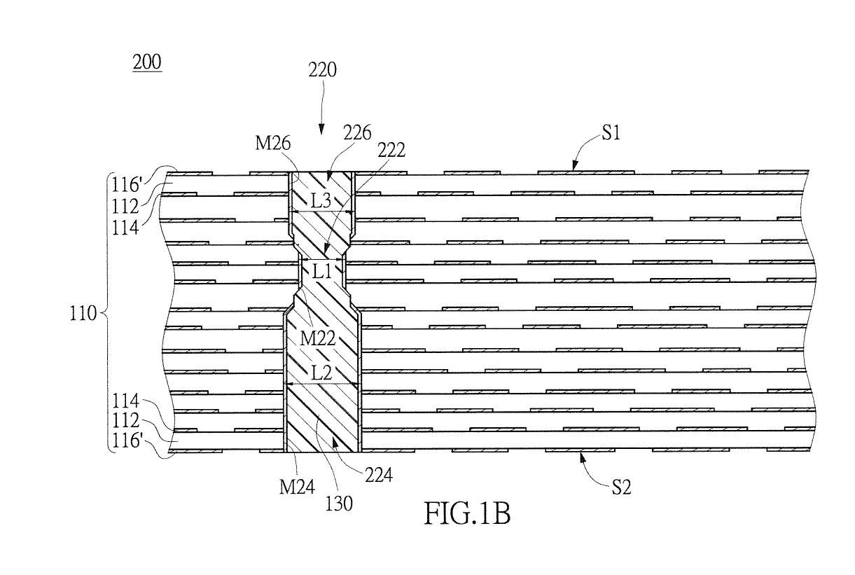

FIG. 1A is a schematic diagram showing a circuit board in accordance with a first embodiment of the instant disclosure. Please refer to FIG. 1A. The circuit board 100 includes a substrate 110 and a through via 120. The substrate 110 includes a plurality of insulation layers 112 and a plurality of circuit layers 114. The insulation layers 112 are alternatively disposed among the circuit layers 114. The through via 120 goes through the entire substrate 110.

The substrate 110 has a first surface S1 and a second surface S2. Specifically, the substrate 110 is a multi-layered board. That is to say the insulation layers 112 and the circuit layers 114 are laminated to form the substrate 110. The first and second surfaces S1, S2 have respectively have circuit layer 114. In other words, the first and second surfaces S1, S2 has routing thereon, for example, bonding pad and traces. In practical use, the arrangement of bonding pad and trace may vary according to intended purpose.

It is worth mentioning the insulation layer 112 is made of preimpregnated material. The preimpregnated material is further categorized into glass fiber prepreg, carbon fiber prepreg and epoxy resin according to the strength. Additionally, the circuit layer 114 is made of copper. The copper foil pattern of the circuit layer 114 can be obtained by microetching. However, the material of the insulation layer 112 and circuit layer 114 is not limited to the abovementioned items.

The through via 120 has portions defining a first portion 122 and a second portion 124. The first portion 122 opens on the first surface S1 while the second portion 124 opens on the second surface S2. The first portion 122 includes a first metal layer M12. The first metal layer M12 is disposed on the wall of the first portion 122. The first portion 122 is electrically connected to at least one circuit layer 114 by the first metal layer M12. The second portion 124 includes a second metal layer M14. The second metal layer M14 is disposed on the wall of the second portion 124. The second portion 124 is electrically connected to at least one circuit layer 114 by the metal layer M14. It should be noted the first portion 122 is electrically connected to the circuit layer 114 among the first surface S1 while the second portion 124 is electrically connected to the circuit layer 114 among the second surface S2.

The first and second portions 122, 124 are electrically insulated. That is to say the first and second metal layers M12, M14 do not have direct contact or electrical connection. The outer diameter L2 of the second portion 124 is larger than the outer diameter L1 of the first portion 122.

Accordingly, different circuit layers 114 can be electrically connected by the first and second portions 122, 124. The first and second portions 122, 124 provides electrical path within the substrate 110. Therefore, the electrical path among different circuit layers 114 is shortened, and the signal transmission speed increases without too much signal loss. Also, the manufacturing cost is reduced because the circuit board does not require blind via or buried via.

The circuit board 100 further includes insulated filling layer 130 to prevent electrical connection between the first and second portions 122, 124. The insulated filling layer 130 is disposed in the through via 120. The insulated filling layer 130 contacts the first and second metal layers M12, M14. In general, the material of the insulated filling layer 130 may be via-filling ink and the ink is added to the through via 120 by screen printing. However, the material and fabrication of the insulated filling layer 130 is not limited to the abovementioned sources.

FIG. 1B is a schematic view of the circuit board in accordance with a second embodiment of the instant disclosure. The circuit board 200 of the second embodiment is similar to the circuit board 100 of the first embodiment. For example, the circuit boards 100, 200 include the plurality of insulation layer 112. The same features are omitted herein to avoid repetition.

Please refer to FIG. 1B. The circuit board 200 of the second embodiment includes the substrate 110 and a through via 220. Similarly, the substrate 110 includes the plurality of insulation layers 112 and the plurality of circuit layers 114. The insulation layers 112 are alternatively disposed in the circuit layers 120. The through via 220 goes through the substrate 110.

In the instant embodiment, the through via 220 has portions defining a first portion 222, a second portion 224 and a third portion. The first portion 222 includes a first metal layer M22 which is disposed on the wall of the first portion 222. The second portion 224 includes a metal layer M24 which is disposed on the wall of the second portion 224. The third portion 226 includes a third metal layer M26 which is disposed on the wall of the third portion 226. It is worth noting the first portion 222 is flanked by the third portion 226 and the second portion 224. The third portion 226 is electrically connected to the circuit layers 114 among the first surface S1 while the second portion 224 is electrically connected to the circuit layers 114 among the second surface S2.

The first, second and third portions 222, 224, 226 are electrically insulated to one another. That is to say the first, second and third metal layers M22, M24. M26 do not have any contact or electrical connection. Furthermore, the outer diameter L2 of the second portion 224 and the outer diameter L3 of the third portion 226 are larger than the outer diameter L1 of the first portion 222.

Different circuit layers 114 are respectively and electrically connected by the first, second and third portions 222, 224, 226. In other words, the first, second and third portions 222, 224, 226 provide electrical path within the substrate 110. Therefore, the electrical path among different circuit layers 114 is shortened, and the signal loss in high speed transmission is reduce. Also, the manufacturing cost is reduced because the circuit board does not require blind via or buried via.

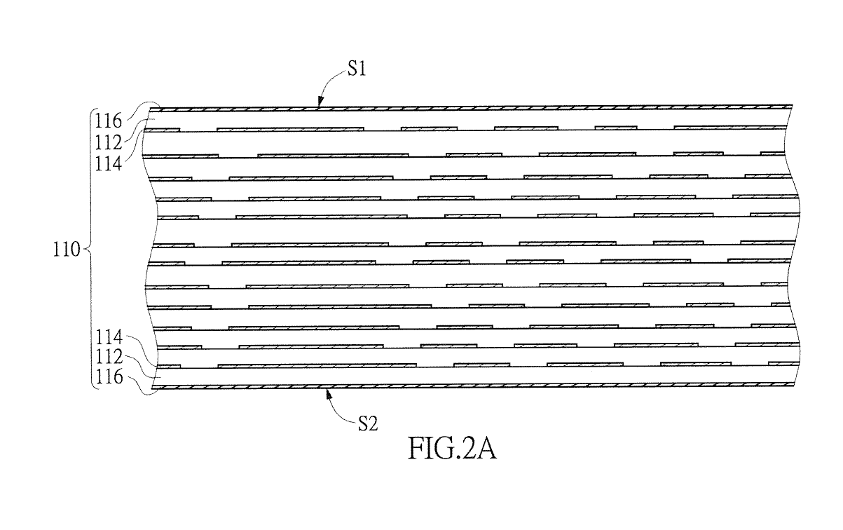

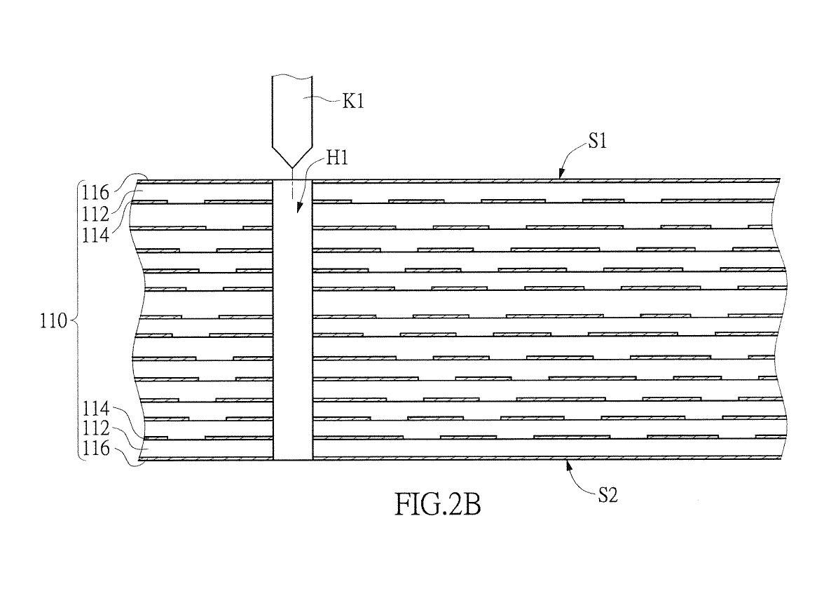

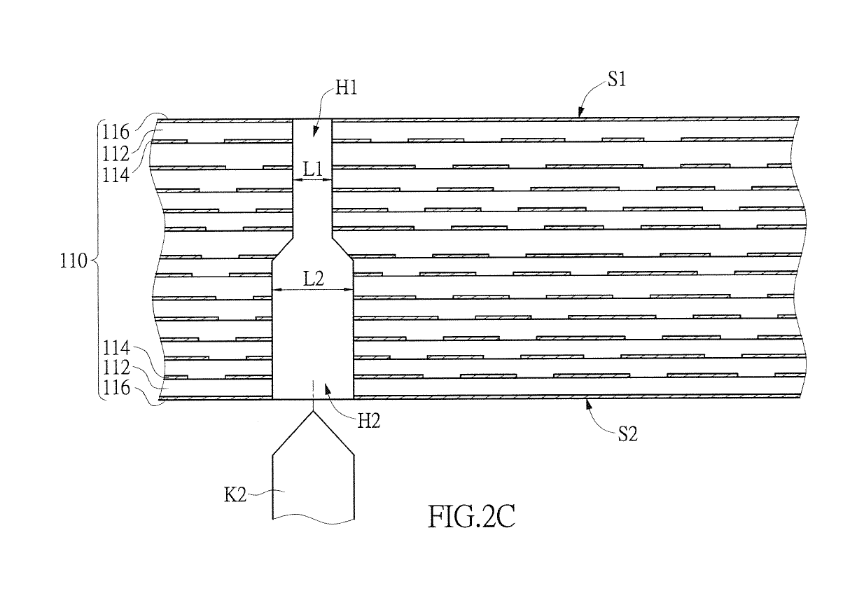

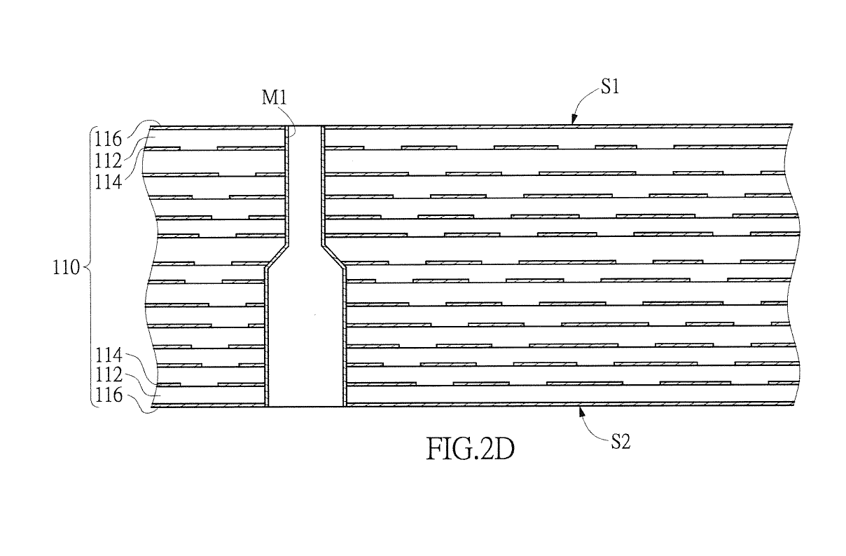

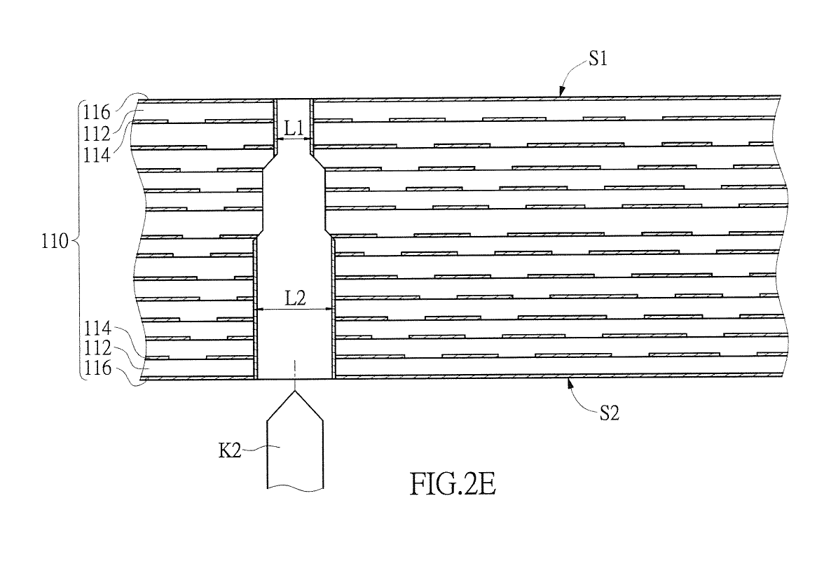

FIGS. 2A to 2E are schematic diagrams showing a method of manufacturing the circuit board in accordance with the first embodiment of the instant disclosure. Please refer to FIGS. 2A to 2E.

Please refer to FIG. 2A. The substrate 110 is provided. The substrate 110 has the first surface S1 and the second surface S2. Specifically, the insulation layers 112 and the circuit layers 114 are laminated on one another to form the substrate 110. The insulation layer 112 is alternatively arranged among the circuit layers 114, and therefore the substrate 110 is a multi-layered circuit board.

Please refer to FIG. 2B. A first hole H1 is formed on the substrate 110 going through the first surface S1 Specifically, a first drill K1 is used to attack the substrate 110 on the first surface S1 to form the first hole H1 which goes through the entire substrate 110. It is worth noting by drilling the first hole H1, the insulation layers 112 are revealed. The diameter of the first hole H1 is designated as L1. In addition, for different intended purposes, the first hole H1 may not go through the entire substrate 110 (not shown). In other words, the drill K1 creates a blind via rather than a through via. However, the instant disclosure is not limited to the instant embodiment.

Please refer to 2C. A second hole H2 is formed on the substrate 110 going through the second surface S2. A second drill K2 is used to form the second hole H2. Specifically, the drill K2 aims at an area where the second hole H2 will meet the first hole within the substrate 110 after drilling. It is worth noting by drilling the second hole H1, the insulation layers 112 are revealed. The diameter of the second hole H2 is designated as L2. The second hole H2 and the first hole H1 meet each other within the substrate 110 on the same location. The diameter L2 of the second hole H2 is larger than the diameter L1 of the first hole H1. Additionally, if the first hole H1 does not go through the entire substrate 110 (not shown), the second hole H2 will meet the first hole H1 within the substrate 110. In more detail, the second drill K2 is directed toward the first hole H1 and attacks the second surface S2 to form the second hole H2.

Please refer to FIG. 2D. The metal layer M1 is formed on the wall of the first and second holes H1, H2 by electroplating. Specifically, the side walls of the revealed insulation layers 112 are metalized because the walls of the first and second holes H1, H2 are covered by the metal layer.

Please refer to FIG. 2E. The metal layer M1 at the boundary of the first and second holes H1, H2 are removed to form the through via 120. Specifically, a drill K or a milling cutter K enters the second hole H2 and peels off the metal layer M1 at the boundary of the first and second holes H1, H2. Accordingly, the first portion 122 and the second portion 124 are formed and the through via 120 is then complete. It should be noted that the size of the drill K or the milling cutter K ranges between the first drill K1 and the second drill K2 such that the drill K or the milling cutter K can enter the second hole H2 and remove a portion of the metal layer M1. Alternatively, the metal layer M1 at the boundary of the first and second holes H1, H2 can be removed by laser burning. The first and second portions 122, 124 are electrically insulated after removing part of the plated metal at the boundary of 122 and 124. Instant disclosure is not limited thereto.

Moreover, please refer back to FIG. 1A. The method of manufacturing the circuit board 100 may also include filling an insulation material to the through via 120 to form an insulated filling layer 130. The reason for the filling is to reduce the rate of electrical connection between the first and second portions 122, 124. In general, the insulation material may be via-filling ink filling the through via 120 by screen printing. The insulated filling layer 130 contacts not only the first metal layer M12 and the second metal layer M14 but also the revealed side wall of the insulation layer 114 at the boundary of the first and second holes H1, H2. In the presence of the insulated filling layer 130, the chance of the first and second portions 122, 124 being electrically connected is further reduced. The material and filling method of the insulated filling layer 130 is not limited to the instant embodiment.

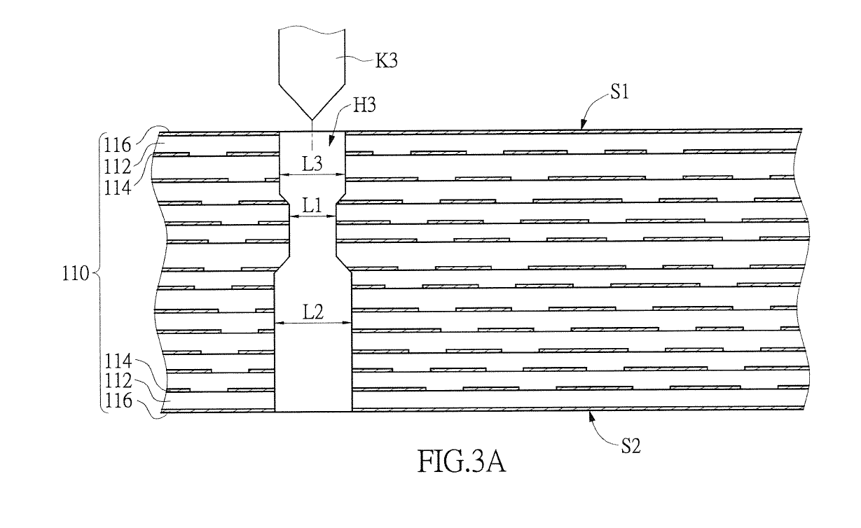

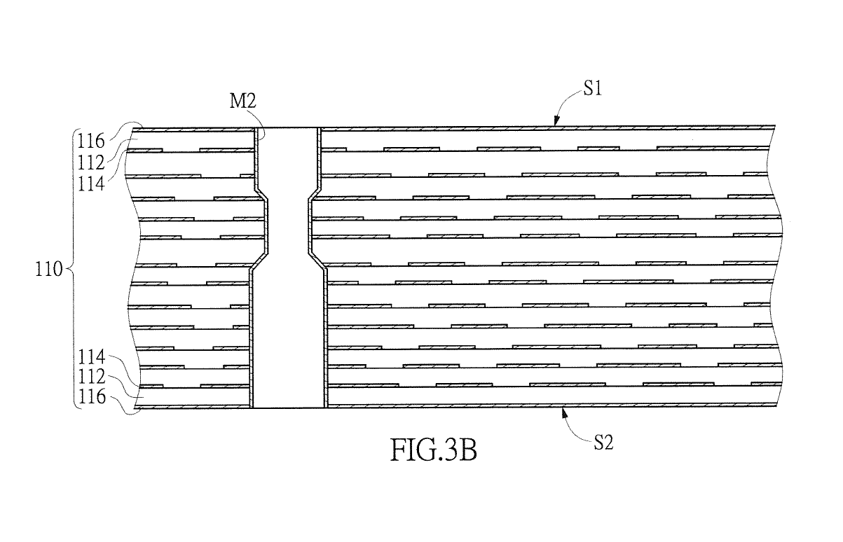

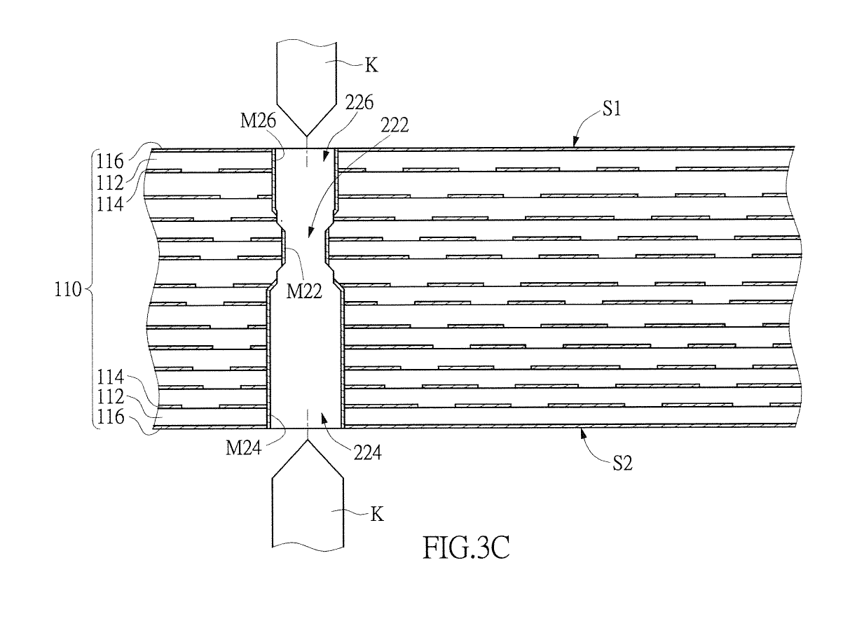

FIGS. 3A to 3C show the method of manufacturing circuit board in accordance with the second embodiment of the instant disclosure. Please refer to FIGS. 3A to 3C.

Firstly, FIG. 2C continues to a step as shown in FIG. 3A. Please refer to FIG. 3A. After the formation of the first and second holes H1, H2, the third hole H3 is formed by enlarging the first hole H1 with a third drill K3. In the instant embodiment, the third hole H3 opens on the first surface S1. That is to say looking down from the first surface S1 the third portion 226 comes first, then the first portion 222 and finally the second portion 224 proximate to the second surface S2. Since the third hole H3 is formed by enlarging a portion of the first hole H1, the diameter of the third hole H3 which is designated as L3 is larger than the diameter L1 of the first hole H1.

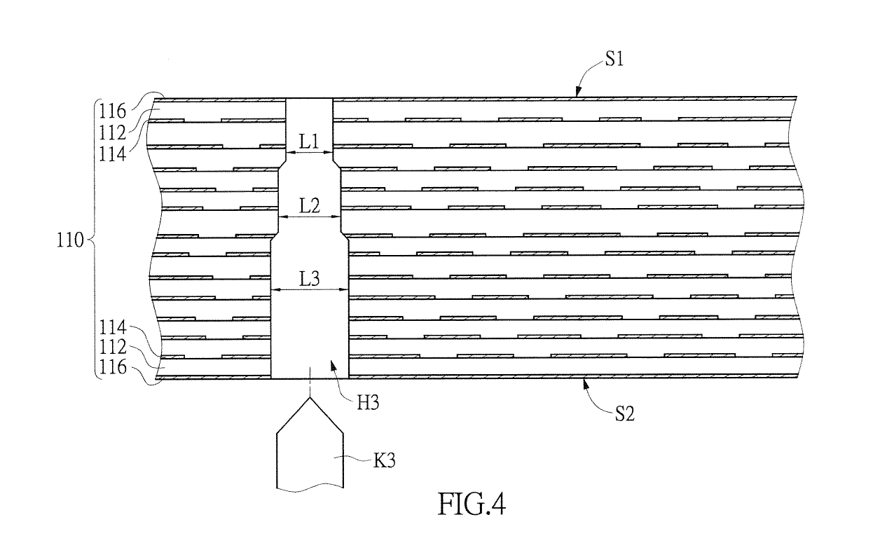

However, in another embodiment, as shown in FIG. 4, the third hole H3 may open on the second surface S2. In other words, the third hole H3 is formed by enlarging the second hole H2. Accordingly, when looking down from the second surface S2, the third portion 226 comes first, then the second portion 224 and finally the first portion 222.

Please refer to FIG. 3B. Subsequently, the metal layer M2 is electroplated on the walls of the first, second and third holes H1, H2, H3. In other words, the side wall of the revealed insulation layer 114 is metalized by electroplating walls of the first, second and third holes H1, H2, H3.

Please refer to FIG. 3C. The metal layer M2 at the boundary of the first and second holes H1, H2 is removed. In addition, the metal layer M2 at the boundary of the first and third holes H1, H3. The through via 220 is then complete. Specifically, the drill K or the milling cutter K enters the second hole H2 and peels off the metal layer M2 at the boundary of the first and second holes H1, H2. Thereby the first and second portions 222, 224 are complete so as the through via 220. It is worth mentioning in the instant embodiment, the size of the drill K or the milling cutter K ranges between the second drill K2 and the third drill K3 such that the drill K or the milling cutter K can enter the second and third holes H2, H3 and remove a portion of the metal layer M2. Alternatively, the metal layer M2 at the boundary of the first and second holes H1, H2 can be removed by laser burning, and the instant disclosure is not limited thereto.

Please refer back to FIG. 1B. The method of manufacturing the circuit board 200 may also include filling an insulation material to the through via 220 to form an insulated filling layer 130. The reason for the filling is to reduce the rate of electrical connection between the first and second portions 222, 224. In general, the insulation material may be via-filling ink filling the through via 220 by screen printing. The insulated filling layer 130 contacts not only the first metal layer M22 and the second metal layer M24 but also the revealed side wall of the insulation layer 114 at the boundary of the first and second holes H1, H2.

Following that, etching is performed. The surface of an outer metal layer 116 is micro-etched to form an outer circuit layer 116′. Conventional etching process can be employed to form the outer circuit layer 116′ and the instant disclosure is not limited thereto.

To sum up, the instant disclosure provides a circuit board and method of manufacturing the same. The circuit board has the first and second portions. The first portion is in electrical connection to at least one circuit layer by the first metal layer while the second portion is in electrical connection to at least one circuit layer by the second metal layer. The first and second portions are mutually electrical insulated, and the diameter of the second portion is larger than that of the first portion. Accordingly, the electrical connection between different circuit layers is shortened, and therefore the signal loss can be reduce in high transmission speed. In addition, the space occupied by the through via is reduced. The cost is also reduced because there is not need to fabricate blind via or buried via.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A circuit board comprising:
a substrate having a first surface and a second surface opposite to the first surface, wherein the substrate includes two outer circuit layers, a plurality of circuit layers and a plurality of insulation layers, the circuit layers and the insulation layers are alternatively sandwiched between the two outer circuit layers; and
a through via going through the substrate, wherein the through via opens on the outer circuit layers and has portions defining a first portion and a second portion, the first portion of the through via is coated with a first metal layer and electrically connected to at least one of the circuit layer by the first metal layer, the second portion of the through via is coated with a second metal layer and electrically connected to at least one of the circuit layer by the second metal layer, the first and second portions are electrically insulted, and the diameter of the second portion is larger than that of the first portion.

2. The circuit board according to claim 1 further comprising an insulated filling layer, wherein the insulated filling layer is disposed in the through via and contacts the first and second metal layers.

3. The circuit board according to claim 1, wherein a third portion of the through via is coated with a third metal layer and electrically connected to at least one circuit layer by the metal layer, and the first portion is sandwich between the second and third portions.

4. A method of manufacturing circuit board comprising:
providing a substrate having a first surface and a second surface opposite to the first surface, wherein the substrate includes two outer circuit layers, a plurality of circuit layers and a plurality of insulation layers, the circuit layers and the insulation layers are alternatively sandwiched between the two outer circuit layers;
forming a first hole going through the first surface and a portion of the substrate;
forming a second hole going through the second surface and a portion of the substrate to meet the first hole, wherein the diameter of the second hole is larger than that of the first hole;
electroplating a metal layer to coat the wall of the first and second holes; and
removing the metal layer at the boundary of the first and second holes to form a through via.

5. The method of manufacturing circuit board according to claim 4, wherein in the step of forming the first and second hole further comprises:
using a first drill to bore the first hole across the first surface and a portion of the substrate; and
using a second drill to bore the second hole across the second surface and a portion of the substrate, wherein the second drill end is larger than the first drill end.

6. The method of manufacturing circuit board according to claim 4, wherein in the step of removing the metal layer further comprises:
using a drill to remove the metal layer at the boundary of the first and second holes which has a drill end sizing between the first and the second drill.

7. The method of manufacturing circuit board according to claim wherein in the step of removing the metal layer further comprises:
using a milling cutter to remove the metal layer at the boundary of the first and second holes which sizes between the first and the second drill.

8. The method of manufacturing circuit board according to claim 4 further comprising:
enlarging a portion of the first hole to form a third hole.

9. The method of manufacturing circuit board according to claim 4 further comprising:
filling an insulation material in the through via.

10. The method of manufacturing circuit board according to claim 4 further comprising:
forming the first hole going through the first surface and the entire substrate.
